(19) United States
(12) Patent Application Publication
(10) Pub. No.: US 2026/0324298 A1
(43) Pub. Date: Oct. 15, 2026

(54) QUANTUM APPARATUS AND METHOD BASED ON A JOSEPHSON JUNCTION RESISTANCE DISPERSION

(71) Applicant: Samsung Electronics Co., Ltd., Suwon-si (KR)

(72) Inventors: Daeyun KIM, Suwon-si (KR); Seonmyeong CHOI, Suwon-si (KR); Hyeokshin KWON, Suwon-si (KR); Kiho KIM, Suwon-si (KR); Jaeho SHIN, Suwon-si (KR); Daeseok HAN, Suwon-si (KR)

(73) Assignee: Samsung Electronics Co., Ltd., Suwon-si (KR)

(21) Appl. No.: 19/465,206

(22) Filed: Jan. 30, 2026

(30) Foreign Application Priority Data
Mar. 6, 2025 (KR) 10-2025-0029203

(51) Int. Cl. H10N 60/12; G06N 10/40; H10N 60/80; H10N 60/82

(52) U.S. Cl. CPC H10N 60/12; G06N 10/40; H10N 60/805; H10N 60/82

(57) ABSTRACT

Provided are a quantum apparatus and method. The quantum apparatus includes a first electrode layer that extends in a first direction on a substrate, a second electrode layer that extends in a second direction on the substrate, a Josephson junction formed by the second electrode layer overlapping the first electrode layer, and capacitor pads that form a resonance circuit with the Josephson junction, wherein the Josephson junction has a first length that is defined as a length of a top edge along which the second electrode layer extends across the first electrode layer in the second direction, and has a second length that is defined as a length of a step edge where the second electrode layer extends upward to overlap or be above the first electrode layer, and wherein a ratio of the first length to the second length corresponds to a resistance dispersion of the Josephson junction.

### CROSS-REFERENCE TO RELATED APPLICATION

This application is based on and claims priority under 35 U.S.C. §119 to Korean Patent Application No. 10-2025-0029203, filed on Mar. 6, 2025 in the Korean Intellectual Property Office, the entire disclosure of which is incorporated herein by reference herein for all purposes.

### BACKGROUND

### 1. Field

The disclosure relates to a quantum apparatus and method based on a Josephson junction resistance dispersion.

### 2. Description of the Related Art

Quantum apparatuses, such as superconducting quantum computers, may utilize quantum characteristics of superconductors. As a non-limiting example, as a superconducting quantum computer, a quantum device may have quantized energy levels based on the oscillation of a Josephson junction and a capacitor. The resonant frequency of a quantum device may affect the accuracy of quantum operations, coupling between quantum devices, and initialization of quantum states.

### SUMMARY

In one general aspect, a quantum apparatus includes a first electrode layer that extends in a first direction on a substrate, a second electrode layer that extends in a second direction on the substrate, a Josephson junction formed by an overlapping of the first electrode layer by the second electrode layer, and capacitor pads that form a resonance circuit together with the Josephson junction, wherein the Josephson junction has a first length that is defined as a length of a top edge, of the Josephson junction, along which the second electrode layer extends across the first electrode layer in the second direction, and has a second length that is defined as a length of a step edge of the Josephson junction where the second electrode layer extends upward to overlap or be above the first electrode layer, and wherein a ratio of the first length to the second length corresponds to a resistance dispersion of the Josephson junction.

The Josephson junction may have a bonding area, defined by the first and second lengths, corresponding to a predetermined resistance of the Josephson junction.

The Josephson junction may have a bonding area, defined by the first and second lengths, corresponding to a predetermined resonant frequency of the resonant circuit.

The resistance dispersion of the Josephson junction may be a dispersion of respective normal resistances of Josephson junctions having a same configuration of the Josephson junction.

The second length may be greater than the first length.

The first length may be a length of the Josephson junction in the second direction, and the second length may be a length of the Josephson junction in the first direction.

A first width of the first electrode layer at the Josephson junction may define the first length, and a second width of the second electrode layer at the Josephson junction may define the second length, and the resistance dispersion of the Josephson junction may be defined by the first and second widths.

The first width may be different from the second width.

The first width may be less than the second width.

The Josephson junction may include a barrier layer arranged between the first electrode layer and the second electrode layer.

The first and second directions may be orthogonal or at a non-zero angle with respect each other.

The first and second directions may be in line and are opposing directions.

The overlapping of the first electrode layer by the first electrode layer may include the second electrode layer extending upward from the substrate to be over the first electrode layer in the second direction and then descending downward from being over the first electrode layer to be on the substrate in the second direction.

The resistance dispersion of the Josephson junction may correspond to a normal resistance of the Josephson junction that may be within a first range of normal resistances along with other first Josephson junctions that also have the first and second lengths and a same first Josephson junction area as the Josephson junction, with the first range being smaller than another range of normal resistances of other second Josephson junctions that have the same first Josephson junction area but a greater ratio of a corresponding first length to a corresponding second length of each of the second Josephson junctions.

The quantum apparatus may further include a quantum integrated circuit that includes the Josephson junction and the other first Josephson junctions, all of which have corresponding normal resistances within the first range, and a control circuit configured to control the quantum integrated circuit.

In one general aspect, a quantum apparatus includes a substrate, and plural quantum devices arranged on the substrate, wherein each of the quantum devices includes a first electrode layer that extends in a first direction on the substrate, a second electrode layer that extends in a second direction on the substrate, a Josephson junction formed by an overlapping of the first electrode layer by the second electrode layer, and capacitor pads that form a resonance circuit together with the Josephson junction, wherein each of the Josephson junctions has a first length that is defined as a length of a top edge, of a corresponding Josephson junction, along which the second electrode layer extends across the first electrode layer in the second direction, and has a second length that is defined as a length of a step edge of the corresponding Josephson junction where the second electrode layer extends upward to overlap or be above the first electrode layer, wherein all of the Josephson junctions have a same ratio of the first length to the second length, the ratio corresponding to a resistance dispersion that each of the Josephson junctions satisfy, and wherein the substrate and the plural quantum devices are arranged as a quantum integrated circuit.

Each of the Josephson junctions may have a bonding area, defined by the first and second lengths, corresponding to a predetermined resistance of the Josephson junctions.

Each of the Josephson junctions may have a bonding area, defined by the first and second lengths, corresponding to a predetermined resonant frequency of the resonant circuit.

In one general aspect, a quantum apparatus includes a quantum integrated circuit including a substrate and plural quantum devices arranged on the substrate, and a control circuit configured to control the quantum integrated circuit, wherein each of the plural quantum devices includes a first electrode layer that extends in a first direction on the substrate, a second electrode layer that extends in a second direction on the substrate, a Josephson junction formed by an overlapping of the first electrode layer by the second electrode layer, and capacitor pads that form a resonance circuit together with the Josephson junction, wherein each of the Josephson junctions has a first length that is defined as a length of a top edge, of a corresponding Josephson junction, along which the second electrode layer extends across the first electrode layer in the second direction, and has a second length that is defined as a length of a step edge of the corresponding Josephson junction where the second electrode layer extends upward to overlap or be above the first electrode layer, and wherein all of the Josephson junctions have a same ratio of the first length to the second length, the ratio corresponding to a resistance dispersion that each of the Josephson junctions satisfy.

Each of the Josephson junctions may have a bonding area, defined by the first and second lengths, corresponding to a predetermined resistance of the Josephson junctions.

Other features and aspects will be apparent from the following detailed description, the drawings, and the claims.

### BRIEF DESCRIPTION OF THE DRAWINGS

FIG. 1 illustrates an example quantum computing device according to one or more embodiments.

FIG. 2 illustrates an example quantum integrated circuit and one or more quantum devices according to one or more embodiments.

FIGS. 3A-3C illustrate example Josephson junctions according to various embodiments.

FIG. 4 illustrates example resistance dispersions of differently configured Josephson junctions.

FIG. 5 illustrates an example resistance of a Josephson junction according to one or more embodiments.

FIG. 6 illustrates an example electronic device according to one or more embodiments.

FIG. 7 illustrates an example method of setting a Josephson junction according to one or more embodiments.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term "may" herein with respect to an example or embodiment (e.g., as to what an example or embodiment may include or implement) means that at least one example or embodiment exists where such a feature is included or implemented, while all examples are not limited thereto. The use of the terms "example", "embodiment", and "example embodiment" herein have a same meaning (e.g., the phrasing 'in an or one example' has a same meaning as 'in an or one embodiment" and 'in an or one example embodiment'), and "one or more examples" has a same meaning as "one or more embodiments" and "one or more example embodiments". Still further, each of multiple or all separately described an/one "example", "embodiment", "example embodiment", as well as "examples", "embodiments", "example embodiments", herein may be included, in combination, in a same embodiment in any combination.

Throughout the specification, when a component or element is described as being "on", "connected to," "coupled to," or "joined to" another component, element, or layer it may be directly (e.g., in contact with the other component, element, or layer) "on", "connected to," "coupled to," or "joined to" the other component, element, or layer or there may reasonably be one or more other components, elements, layers intervening therebetween. When a component, element, or layer is described as being "directly on", "directly connected to," "directly coupled to," or "directly joined" to another component, element, or layer there can be no other components, elements, or layers intervening therebetween. Likewise, expressions, for example, "between" and "immediately between" and "adjacent to" and "immediately adjacent to" may also be construed as described in the foregoing.

As used herein, the term "and/or" includes any one and any combination of any two or more of the associated listed items. The phrases "at least one of A, B, and C", "at least one of A, B, or C", and the like are intended to have disjunctive meanings, and these phrases "at least one of A, B, and C", "at least one of A, B, or C" (e.g., each phrase may include any one of the respective items alone, all of the items listed together, and all possible combinations thereof), and the like also include examples where there may be one or more of each of A, B, and/or C (e.g., any combination of one or more of each of A, B, and C), unless the corresponding description and embodiment necessitates such listings (e.g., "at least one of A, B, and C") to be interpreted to have a conjunctive meaning.

Although terms such as "first," "second," and "third", or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles "a," "an," and "the" are intended to include the plural forms as well, unless the context clearly indicates otherwise. As non-limiting examples, terms "comprise" or "comprises," "include" or "includes," and "have" or "has" specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms "comprise" or "comprises," "include" or "includes," and "have" or "has" specify the presence of stated features, numbers, operations, members, elements, and/or combinations thereof, other embodiments may exist where one or more of the stated features, numbers, operations, members, elements, and/or combinations thereof are not present.

Spatially relative terms such as "above," "upper," "below," and "lower" may be used herein for ease of description to describe one element’s relationship to another element as shown in the figures. Such spatially relative terms are intended to encompass different orientations of the device in use or operation in addition to the orientation depicted in the figures. For example, if the device in the figures is turned over, an element described as being "above" or "upper" relative to another element will then be "below" or "lower" relative to the other element. Thus, the term "above" encompasses both the above and below orientations depending on the spatial orientation of the device. The device may also be oriented in other ways (for example, rotated 90 degrees or at other orientations), and the spatially relative terms used herein are to be interpreted accordingly

Due to manufacturing techniques and/or tolerances, variations of the shapes shown in the drawings may occur. Thus, the examples described herein are not limited to the specific shapes shown in the drawings, but include changes in shape that occur during manufacturing.

Unless otherwise defined, all terms, including technical and scientific terms, used herein have the same meaning as commonly understood by one of ordinary skill in the art to which this disclosure pertains and specifically in the context on an understanding of the disclosure of the present application. Terms, such as those defined in commonly used dictionaries, are to be interpreted as having a meaning that is consistent with their meaning in the context of the relevant art and specifically in the context of the disclosure of the present application, and are not to be interpreted in an idealized or overly formal sense unless expressly so defined herein.

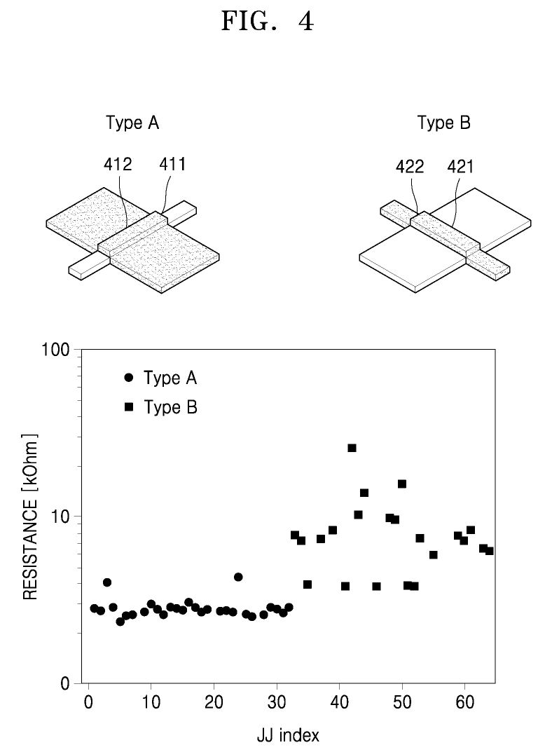

Herein, the term "resistance" in the context of a Josephson junction means a “normal resistance”. For example, a Josephson junction's "normal resistance" refers to its resistance in the non-superconducting state, typically denoted as R_{N}. The normal resistance may mean the resistance of the Josephson junction at room temperature. As another example, the normal resistance may be the resistance when the corresponding current exceeds its critical current or when the Josephson junction is above its critical temperature (T_{C})(e.g., the temperature above which superconductors forming the junction lose their superconducting properties and transition to a ‘normal’ (resistive) state). Typical values for the normal resistance in a Josephson junction may range from a few ohms to hundreds of ohms, though this can vary widely, such as from .1 to 100k ohms, as non-limiting examples. Previously, the exact normal resistance value may depend on factors like the Josephson junction's area, barrier thickness, and material properties. For precise applications normal resistance may be characterized experimentally, as it influences the junction’s behavior, such as the critical current (I_{C}) via the Ambegaokar-Baratoff relation, where I_{C}R_{N} ∝ Δ (the superconducting gap). Further, previous research suggests that there may be a one to one correspondence between the area of the Josephson junction and normal resistance. However, the inventors have determined that normal resistance may be dependent on a different factor, of an aspect ratio between the electrodes layers of the Josephson junction, and determined that some aspect ratios may decrease the normal resistance dispersion between (e.g., experimentally measured) respective normal resistances for different Josephson junctions of the same materials and configuration (e.g., see FIG. 4 and corresponding discussion below).

Herein the term "resistance dispersion" (or phrases dispersion of normal resistance or dispersion of resistance) may mean a dispersion (i.e., distribution or variability) of this normal resistance for different Josephson junctions. For example, the resistance dispersion of a Josephson junction may mean the degree to which the respective normal resistances of multiple Josephson junctions (e.g., of same materials and configurations) are dispersed. For example, an example resistance dispersion may also be reflected through the normal resistances being within a range of normal resistances, and in an example depending on the set aspect ratio of the electrode layers of the Josephson junction, where the range of the respective normal resistances of multiple first Josephson junctions with electrode layers being configured with one aspect ratio may be less than the range of the respective normal resistances of multiple second Josephson junctions with electrode layers being configured with a different aspect ratio. For example, in this example, the multiple first Josephson junctions may more reliably replicate similar or same normal resistances compared to the multiple second Josephson junctions.

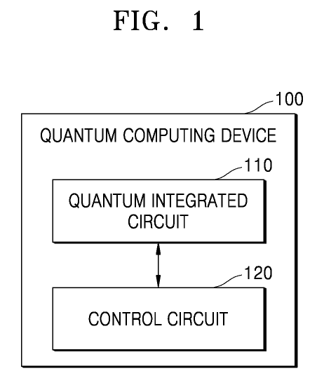

FIG. 1 illustrates an example quantum computing device 100 according to one or more embodiments.

The quantum computing device 100 is configured to perform computations using quantum mechanical phenomena such as superposition and entanglement. The quantum computing device 100 may be a superconducting quantum computing device that implements qubits in a superconducting state.

The quantum computing device 100 may include a quantum integrated circuit 110 and a control circuit 120. The quantum computing device 100 may also be representative of additional components of a computing system, that may include a user interface, an input/output device, communication transceivers, or the like.

The quantum integrated circuit 110 may be configured to perform a quantum operation. The quantum integrated circuit 110 may include one or more quantum devices. Here, the quantum device may be a device including a resonance circuit of a Josephson junction and a capacitance (referred to herein as a capacitor). For example, the quantum device may be a qubit or a qubit coupler. The quantum integrated circuit 110 may include a quantum gate implemented with one or more qubits or a quantum circuit implemented with one or more quantum gates.

The control circuit 120 may be configured to control the quantum integrated circuit 110. For example, the control circuit 120 may be representative of a transmission line (e.g., a drive line or a readout line), or a resonator. Furthermore, the control circuit 120 may be configured to control the overall operation of the quantum computing device 100. For example, the control circuit 120 may be representative of control circuitry that includes a quantum circuit, a photon circuit, and/or an electronic circuit for controlling the quantum computing device 100.

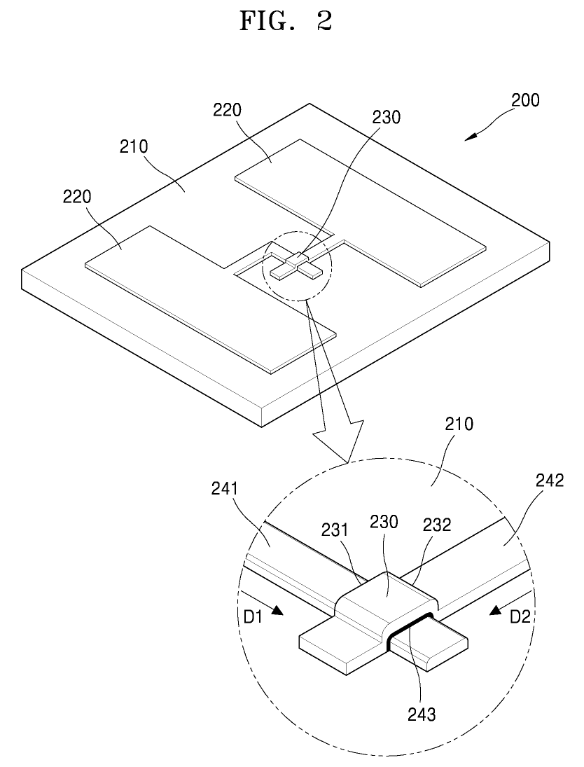

FIG. 2 illustrates an example quantum integrated circuit 200 and quantum device according to one or more embodiments.

The upper figure of FIG. 2 shows a quantum integrated circuit 200 including a quantum device with a Josephson junction 230. In the lower figure of FIG. 2, the Josephson junction 230 of the quantum device is enlarged.

The quantum integrated circuit 200 may include a substrate 210 and is representative of one or more quantum devices arranged on the substrate 210. The substrate 210 may be a silicon substrate. Alternatively, a silicon on insulator (SOI) substrate, a sapphire substrate, and an insulating substrate made of other various materials may be used as the substrate 210.

Each quantum device arranged on the substrate 210 includes respective capacitor pads 220 and a corresponding Josephson junction 230, respectively representing the one or more quantum devices. The capacitor pads 220 and the Josephson junction 230 form a nonlinear LC resonance circuit. The quantum device may operate as a qubit or a qubit coupler.

While noting that the same is also applicable to the other quantum devices arranged on the substate, embodiments may be explained through the description of one of the quantum devices. Thus, the quantum device includes a first electrode layer 241 and a second electrode layer 242 arranged on a substrate 210. A Josephson junction 230, made up of the first electrode layer 241, a barrier layer 243, and the second electrode layer 242, is formed in an overlapping region of the first and second electrode layers 241 and 242.

The capacitor pads 220 and the first and second electrode layers 241 and 242 may include superconductors. For example, the capacitor pads 220 and the first and second electrode layers 241 and 242 may include at least one of aluminum (Al), neobium (Nb), indium (In), alpha-tantalium (α-Ta), titanium (Ti), lead (Pb), vanadium (V), or compounds thereof (e.g., NbN, NbTiN, TiN, or VN), but are not limited thereto. The barrier layer 243 may be an oxide layer, as a non-limiting example.

The first electrode layer 241 may extend in a first direction D1 on the substrate 210 as illustrated in FIG. 2. The second electrode layer 242 may extend in a second direction D2 on the substrate 210 as illustrated in FIG. 2. The first direction D1 may be a direction perpendicular to the second direction D2. Alternatively, the first direction D1 may not be perpendicular to the second direction D2. For example, the first electrode layer 241 extending in the first direction D1 may intersect the second electrode layer 242 extending in the second direction D2 at a non-perpendicular angle or the first electrode layer 241 may intersect the second electrode layer 242 in-line from opposite directions.

The second electrode layer 242 may extend (in the second direction D2 on the substrate 210) to ascend from the substrate 210 to above the first electrode layer 241 and then descend back from above the first electrode layer 241 down to the substrate 210. Depending on the extension direction or the manufacturing process of the first and second electrode layers 241 and 242, the second electrode layer 242 may likewise (in the second direction D2 on the substrate 210) ascend from the substrate 210 to above the first electrode layer 241 without descending back from above the first electrode layer 241 down to the substrate 210 (i.e., the second electrode layer 242 may cease after the Josephson junction or overlay the first electrode layer 241 after the Josephson junction.

The Josephson junction 230 may have top edges 231 and step edges 232 defined by the shape of the second electrode layer 242, e.g., due to an example deposition of the second electrode layer 242. Each of the top edges 231 may be an upper boundary of the Josephson junction 230 and extend in the second direction D2 of the Josephson junction 230. Each of the step edges 232 may be an upper boundary of the Josephson junction 230 and extend in the first direction D1 of the Josephson junction 230.

A ratio of a length of the top edge 231 to a length of the step edge 232 may affect the accuracy and reproducibility of the resonant frequency of the quantum device by affecting the resistance dispersion of the Josephson junction 230. For example, the resonant frequency of the resonance circuit may vary according to the normal resistance of the Josephson junction 230. As the dispersion of the normal resistance decreases between different Josephson junctions, a quantum device having a Josephson junction reliably close to a predetermined normal resistance may be manufactured. The dispersion of the resistance of the Josephson junction 230 may vary according to the ratio of the length of the top edge 231 to the length of the step edge 232. Therefore, if the ratio of the length of the top edge 231 to the length of the step edge 232 is determined so that the Josephson junction 230 has a low resistance dispersion, the accuracy and reproducibility of the resonant frequency of the quantum device may be increased.

Accordingly, the Josephson junction 230 may have a ratio of a length of the top edge 231 to a length of the step edge 232 corresponding to a predetermined resistance dispersion. Here, the predetermined resistance dispersion may be a value determined so that the resonant frequency has high accuracy and reproducibility. When the quantum integrated circuit 200 (or quantum computing device) includes a plurality of quantum devices having such a Josephson junction 230, the normal resistances of the Josephson junctions of the plurality of quantum devices may satisfy a predetermined resistance dispersion. Accordingly, the plurality of quantum devices may have a same or substantially same resonant frequency with high accuracy and reproducibility, and the quantum integrated circuit 200 (or quantum computing device) having excellent performance may be provided. For example, it is found that resonant frequency of a quantum device may affect the accuracy of quantum operations, coupling between quantum devices, and initialization of quantum states, may be an important factor in determining the performance of superconducting quantum computers, and the more accurate and reproducible the resonant frequencies of quantum devices, the greater the performance of superconducting quantum computers may be, representing non-limiting example technological improvements in the field of quantum apparatuses, such as quantum devices, quantum integrated circuits, and quantum computing devices, as non-limiting examples.

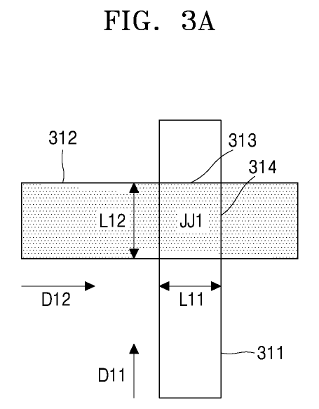

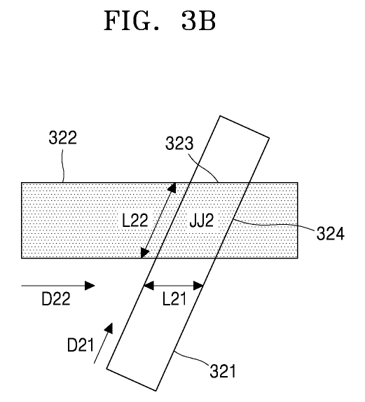

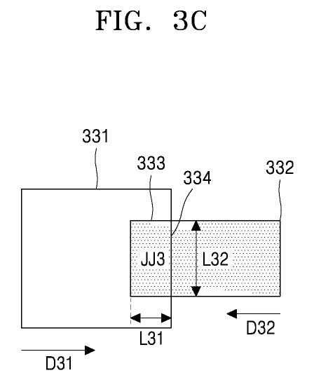

FIG. 3A illustrates an example Josephson junction JJ1 according to one or more embodiments.

In an embodiment, a first electrode layer 311 extends in a first direction D11. A second electrode layer 312 extends in a second direction D12. The Josephson junction JJ1 is formed in an overlapping region of the first and second electrode layers 311 and 312. The first direction D11 and the second direction D12 are orthogonal (i.e., perpendicular) to each other.

Each of top edges 313 of the Josephson junction JJ1 may be an edge in which the second electrode layer 312 extends on the first electrode layer 311 in the second direction D12. In other words, the top edges 313 may be edges of the second electrode layer 312 intersecting the first electrode layer 311 in the second direction D12.

One of step edges 314 of the Josephson junction JJ1 may be an edge on which the second electrode layer 312 ascends from a substrate (for example) up to above the first electrode layer 311. The other of the step edges 314 may be an edge in which the second electrode layer 312 descends down from above the first electrode layer 311 down to the example substrate. In other words, the step edges 314 may be edges of the second electrode layer 312 intersecting the first electrode layer 311 in the first direction D11. Herein, references to a second electrode layer overlapping a first electrode layer to form a Josephson junction mean that the second electrode layer is disposed (above the first electrode layer) farther away from the substrate than the first electrode layer. With respect to ‘step edges’ herein in examples, it is not necessary to delineate where a step edge of a second electrode layer starts or finishes along the extending direction of the second electrode layer, as the length of the step edge is the measure that is considered in the setting of the ratio of the Josephson junction discussed herein for a predetermined (e.g., desired) resistance dispersion. For example, the length of each of the step edges 314 are respectively equal to the corresponding width of the second electrode layer 312 generally at the ascending and descending areas of the second electrode layer 312.

Each of the top edges 313 has a first length L11, and each of the step edges 314 has a second length L12. A ratio of the first length L11 to the second length L12 may correspond to the predetermined resistance dispersion. Here, since the first direction D11 and the second direction D12 are orthogonal to each other, a ratio of the first length L11 to the second length L12 is an aspect ratio. With respect to ‘top edges’ herein in examples, it is also not necessary to delineate where a top edge of a first electrode layer starts or finishes toward a second electrode layer, as the length of the top edge is the measure that is considered in the setting of the ratio of the Josephson junction discussed herein for a predetermined (e.g., desired) resistance dispersion. For example, the length of each of the top edges 313 are respectively equal to the corresponding width of the first electrode layer 311. As another example, the length of the top edges in the below discussed example of FIG. 3C would correspond to the respective extent (or length) of overlap by the second electrode layer 332 (over the first electrode layer 331) in the direction D32 of the second electrode layer 332.

As the second length L12 is increased and the first length L11 remains the same (compared to an original configuration of the Josephson junction) in another configuration of the Josephson junction, the second length L12 is increased more than an increase in the first length L11 in the other configuration of the Josephson junction, or the second length L12 is decreased less than a decrease in the first length L11 in the other configuration of the Josephson junction, the resistance dispersion of the other Josephson junction may decrease compared to the resistance dispersion of the original Josephson junction. Thus, according to this relationship and as a non-limiting example, the resistance dispersion of the Josephson junction JJ1 may be set in advance to be low, and the ratio of the first length L11 to the second length L12 corresponding to a predetermined resistance dispersion may be a ratio in which the second length L12 is greater than the first length L11.

The resistance of the Josephson junction JJ1 may vary depending on a bonding area of the Josephson junction JJ1. In addition, a resonant frequency of the resonance circuit may vary depending on the resistance of the Josephson junction JJ1. In this relationship, the Josephson junction JJ1 may have a bonding area corresponding to a predetermined resistance. Furthermore, the Josephson junction JJ1 may have a bonding area corresponding to a predetermined resonant frequency.

When the bonding area of the Josephson junction JJ1 is fixed, the resistance dispersion of the Josephson junction JJ1 may be lowered as the second length L12 increases in the ratio of the first length L11 to the second length L12. In this relationship, the first length L11 and the second length L12 of the Josephson junction JJ1 may be determined to satisfy a predetermined resistance dispersion. In detail, the Josephson junction JJ1 may have a first length L11 and a second length L12 that satisfy a ratio between the first length L11 and the second length L12 corresponding to a predetermined resistance dispersion among lengths satisfying a predetermined bonding area. The resistance dispersion of the Josephson junction JJ1 may be determined in advance to be low, and the first length L11 corresponding to the predetermined resistance dispersion may be less than the second length L12 corresponding to the predetermined resistance dispersion.

As discussed above, the first length L11 may be the width of the first electrode layer 311, and the second length L12 may be the width of the second electrode layer 312. Accordingly, each of the first electrode layer 311 and the second electrode layer 312 at the Josephson junction may have a width corresponding to a predetermined resistance dispersion of the Josephson junction. The width of the first electrode layer 311 and the width of the second electrode layer 312 may be different from each other according to the predetermined resistance dispersion. The resistance dispersion of the Josephson junction JJ1 may be set in advance to be low, and the width of the first electrode layer 311 corresponding to the predetermined resistance dispersion may be less than the width of the second electrode layer 312 corresponding to the predetermined resistance dispersion.

FIG. 3B illustrates an example Josephson junction JJ2 according to one or more embodiments.

Descriptions that are redundant to those with reference to FIG. 3A are omitted.

In an embodiment, a first electrode layer 321 extends in a first direction D21. A second electrode layer 322 extends in a second direction D22. The Josephson junction JJ2 is formed in an overlapping region of the first and second electrode layers 321 and 322. The first direction D21 and the second direction D22 cross each other but are not orthogonal to each other.

Each of top edges 323 has a first length L21, and each of step edges 324 has a second length L22. A ratio of the first length L21 to the second length L22 may correspond to a predetermined resistance dispersion.

When the resistance dispersion of the Josephson junction JJ2 is set in advance to be low, the ratio of the first length L21 to the second length L22 corresponding to the predetermined resistance dispersion may be a ratio in which the second length L22 is greater than the first length L21. In addition, the first length L21 corresponding to the predetermined resistance dispersion may be less than the second length L22 corresponding to the predetermined resistance dispersion.

The first length L21 is proportional to the width of the first electrode layer 321 (i.e., proportional with respect to the angle between the first direction D21 and the second direction D22), and the second length L12 is proportional to the width of the second electrode layer 322. Accordingly, each of the first electrode layer 321 and the second electrode layer 322 may have a width corresponding to a predetermined resistance dispersion of the Josephson junction. When the resistance dispersion of the Josephson junction JJ2 is set in advance to be low, the width of the first electrode layer 321 corresponding to the predetermined resistance dispersion may be less than the width of the second electrode layer 322 corresponding to the predetermined resistance dispersion.

FIG. 3C illustrates an example Josephson junction JJ3 according to one or more embodiments.

Descriptions that are redundant to those with reference to FIG. 3A are omitted.

In an embodiment, a first electrode layer 331 extends in a first direction D31. A second electrode layer 332 extends in a second direction D32. The Josephson junction JJ3 is formed in an overlapping region of the first and second electrode layers 331 and 332. The first electrode layer 331 extending in the first direction D31 may intersect the second electrode layer 332 extending in the second direction D32 in-line from the opposite first and second directions D31,D32.

Each of top edges 333 has a first length L31, and a step edge 334 has a second length L32. A ratio of the first length L31 to the second length L32 may correspond to a predetermined resistance dispersion.

When the resistance dispersion of the Josephson junction JJ3 is set in advance to be low, the ratio of the first length L31 to the second length L32 corresponding to the predetermined resistance dispersion may be a ratio in which the second length L32 is greater than the first length L31. In addition, the first length L31 corresponding to the predetermined resistance dispersion may be less than the second length L32 corresponding to the predetermined resistance dispersion.

FIG. 4 illustrates example resistance dispersions of differently configured Josephson junctions.

The graph of FIG. 4 shows the dispersions of the normal resistances of 32 Josephson junctions having a Type A configuration and 32 Josephson junctions having a Type B configuration. The Josephson junctions of type A and the Josephson junctions of type B have the same bonding area, but lengths of step edges and top edges are different between Type A and Type B. The Josephson junctions of Type A have the same configurations, with the step edges 412 being longer than the top edges 411. The Josephson junctions of Type B have the same configurations, with the step edges 422 being shorter than the top edges 421.

The resistance dispersion of the Josephson junctions of type A is less than the resistance dispersion of the Josephson junctions of type B (i.e., there is a substantially greater variability and range in the resistances in the Josephson junctions of type B compared to the variability and range in the resistances of the Josephson junctions of type A), and from this, it may be seen that the resistance dispersion may vary depending on the length ratios of the top edges to the step edges. In detail, the longer the step edges are than the top edges, the lower the resistance dispersion may be. Due to the lower resistance dispersion, it can also be said that the longer the step edges, the higher the reproducibility of the resistance of the Josephson junction, and thus the accuracy and reproducibility of the resonant frequency of the quantum device of Josephson junctions of type A (or quantum integrated circuit with Josephson junctions of type A) may increase compared to another quantum device of Josephson junctions of type B (or another quantum integrated circuit with Josephson junctions of type B).

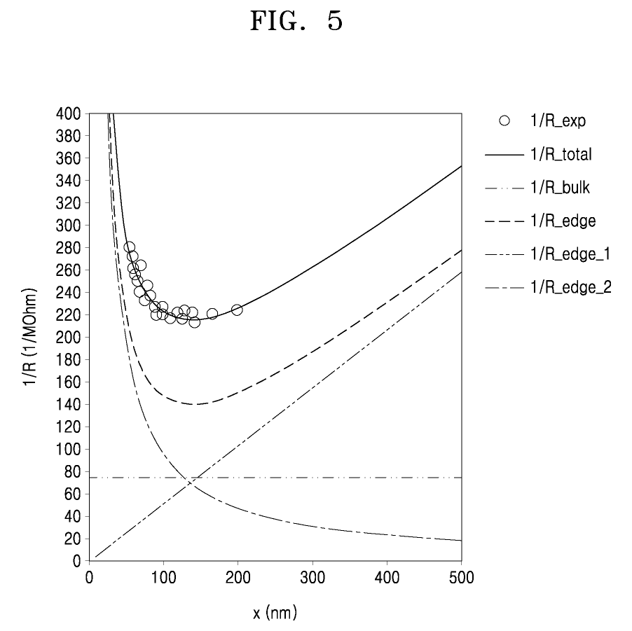

FIG. 5 illustrates an example resistance of a Josephson junction according to one or more embodiments.

The graph of FIG. 5 shows the relationship between a length x of respective step edges of Josephson junctions having a fixed (i.e., same) bonding area and a normal resistance R. The total resistance (1/R_total) of the Josephson junctions was obtained through data fitting of an experimental resistance (1/R_exp).

The total resistance (1/R_total) of the Josephson junctions is the sum of a resistance component (1/R_bulk) by planes and a resistance component (1/R_edge) by edges. The resistance component (1/R_edge) by edges is the sum of a resistance component (1/R_edge_1) by a top edge and a resistance component (1/R_edge_2) by a step edge. Even if the bonding area of the Josephson junctions are the same, it may be seen that different length ratios between the step edge and the top edge may result in different resistance components by the edge, resulting in different total resistances. This change in resistance may be compensated for by adjusting the resistivity of the Josephson junction. For example, a change in resistance may be compensated for by changing the thickness of the barrier layer and generating the Josephson junction with the changed thickness of the barrier layer.

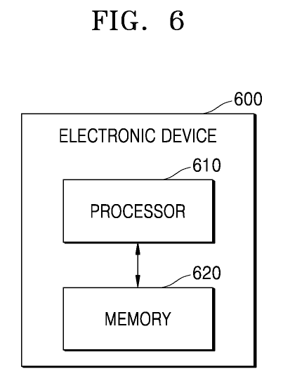

FIG. 6 illustrates an example electronic device 600 according to one or more embodiments.

The electronic device 600 may be configured to set a configuration of a respective Josephson junction of one or more quantum devices, as well as Josephson junctions of a quantum integrated circuit or a quantum computing device, in consideration of the resistance dispersion of each Josephson junction. The electronic device 600 may include a processor 610 and a memory 620.

The processor 610 may control overall operations of the electronic device 600. For example, the processor 610 may control the overall operations of the electronic device 600 to set a configuration of the Josephson junction by executing one or more instructions (i.e., code) stored in the memory 620. The instructions may also be stored as a program or application, as a non-limiting example. There may be one or more processors 610.

For example, the processor 610 is representative of at least one of a central processing unit (CPU), a microprocessor, a graphic processing unit (GPU), application specific integrated circuits (ASICs), digital signal processing devices (DSPs), digital signal processing devices (DSPDs), programmable logic devices (PLDs), field programmable gate arrays (FPGAs), an application processor, a network processing unit (NPU), or an artificial intelligence-only processor configured with a hardware structure specialized in the processing of an artificial intelligence model, but is not limited thereto.

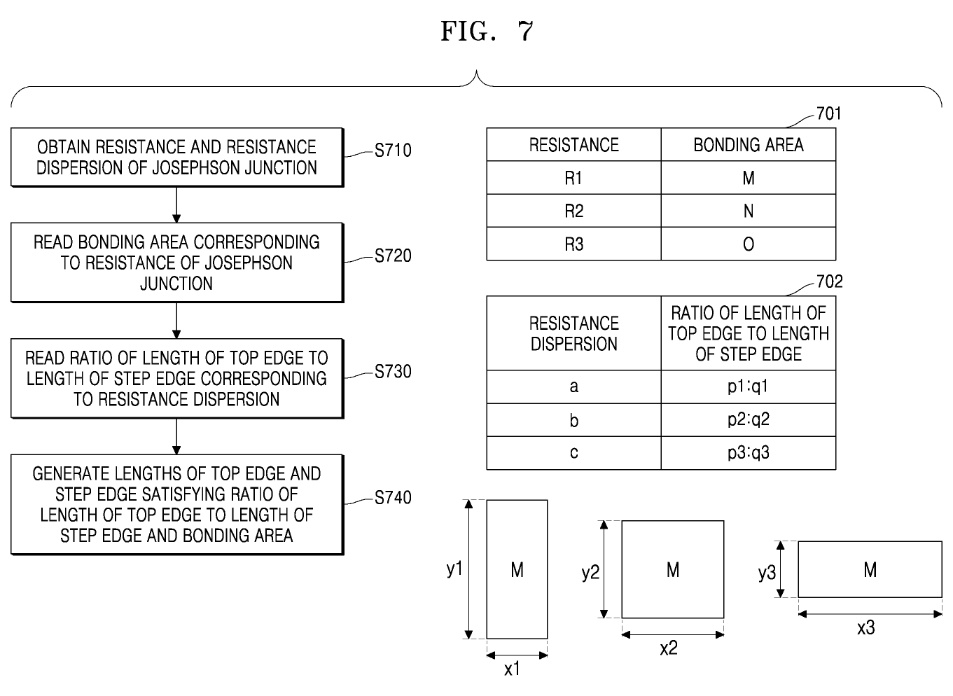

The memory 620 may store the instructions, as well as other data structures (e.g., tables 701 and 702 of FIG. 7, as a non-limiting example), readable by the processor 610. Operations performed by the processor 610 may be implemented by executing the instructions to cause the electronic device to perform one or more or all determining or setting operations described herein, as non-limiting example. For example, the memory 620 may store one or more instructions that, when executed by the processor 610, cause the electronic device 600 to set a configuration of respective Josephson junctions of a quantum device, quantum integrated circuit, or quantum computing device.

The memory 620 may include a flash memory type, a hard disk type, a multimedia card micro type, and a card type memory (e.g., secure digital (SD) or extreme digital (XD) memory), and may include a non-volatile memory including at least one of read-only memory (ROM), electrically erasable programmable read-only memory (EEPROM), programmable read-only memory (PROM), a magnetic memory, a magnetic disk, or an optical disk, and a volatile memory such as a random access memory (RAM) or a static random access memory (SRAM).

FIG. 7 illustrates an example method of setting a Josephson junction according to one or more embodiments.

A processor (e.g., the processor 610 of FIG. 6) may perform a process for setting a configuration of a Josephson junction of one or more quantum devices, a quantum integrated circuit, and a quantum computing device with the set configuration.

In operation S710, the processor acquires a resistance and a resistance dispersion of a Josephson junction.

The processor may obtain the resistance and resistance dispersion of the Josephson junction by receiving a user input or reading a value stored in a memory (e.g., the memory 620 of FIG. 6). Alternatively, the processor may calculate the resistance and corresponding resistance dispersion for a set resonant frequency or other design parameters, for example.

In operation S720, the processor reads, from the memory, a bonding area of a respective Josephson junction corresponding to the obtained resistance.

For the reading of the bonding area, the memory may store a first lookup table 701 that includes different resistances and corresponding bonding areas for respective Josephson junctions. The processor may obtain the bonding area of operation S720 by reading, from the first lookup table 701, a bonding area that corresponds to the resistance obtained in operation S710. For example, if the acquired resistance is R1, the processor may read, from the first lookup table 701, M, which is a corresponding bonding area.

In operation S730, the processor reads, from the memory, a ratio of a length of a top edge to a length of a step edge for a Josephson junction corresponding to the obtained resistance dispersion.

For the reading of the ratio, the memory may store a second lookup table 702 that includes different resistance dispersions for different Josephson junctions and their corresponding ratios of respective lengths of top edge to lengths of step edges. The processor may obtain the ratio of the length of the top edge to the length of the step edge of operation S730 by reading, from the second lookup table 702, the ratio of the length of the top edge to the length of the step edge corresponding to the resistance dispersion obtained in operation S710. For example, if the obtained resistance dispersion is b, the processor may read, from the second lookup table 702, p2:q2, which is a length ratio of the top edge to the step edge which correspond to each other.

The stored length ratio between the top edge and the step edge for a corresponding resistance dispersion in the lookup table 702 may be that length ratio that minimizes the corresponding resistance dispersion. The length ratio between the top edge and the step edge that minimize the resistance dispersion may be a ratio that maximizes the length of the step edge, that is, minimizes the length of the top edge. Here, the minimum value of the length of the top edge may be determined by manufacturing process conditions of the quantum device. Since the length of the top edge may be the width of the first electrode layer or proportional to the width of the first electrode layer, in other words, the length ratio between the top edge and the step edge that minimize the resistance dispersion may be a ratio that minimizes the width of the first electrode layer. Here, the minimum value of the width of the first electrode layer may be determined by manufacturing process conditions of the quantum device. For example, when a Josephson junction is manufactured by lithography, the minimum value of the length of the top edge or the minimum value of the width of the first electrode layer may be determined by a minimum distance between photoresists.

In operation S740, the processor sets the lengths of the top edge and the step edge that satisfy the ratio of the length of the top edge to the length of the step edge and the bonding area (e.g., based on the arcaturing process). In an example, operation S740 may further include the processor controlling a lithographic manufacturing system to generate at least a quantum device with one or more Josephson junctions (and corresponding capacitances connected through the first and second electrode layers).

Among the lengths of the top edges (e.g., x1 to x3) and the lengths of the step edges (e.g., y1 to y3) that satisfy the bonding area (e.g., M), the processor may obtain the lengths (e.g., x1 and y1) of the top edge and the step edge that satisfy a ratio (e.g., p2:q2) of the length of the top edge to the length of the step edge. Alternatively, the processor may derive the lengths (e.g., x1 and y1) of the top edge and the step edge using the bonding area (e.g., M) and the length ratio (e.g., p2:q2) of the top edge to the step edge.

By setting the configuration of a Josephson junction in consideration of not only the resistance of the Josephson junction but also the resistance dispersion, the accuracy and reproducibility of the resistance of the Josephson junction may be improved, thereby increasing the accuracy and reproducibility of the resonant frequency of the quantum device.

The processor, memory, quantum integrated circuit, and control circuitry, described herein, including descriptions with respect to respect to FIGS. 1-7, are implemented by or representative of hardware components. As described above, or in addition to the descriptions above, examples of hardware components that may be used to perform the operations, such as with respect to the processor, memory, and controller (or control circuitry) (and any example additionally included circuitry of the quantum integrated circuit in addition to the one or more quantum devices of the same) described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit (ALU), a digital signal processor (DSP), a microcomputer, a programmable logic controller, a field-programmable gate array (FPGA), a programmable logic array (PLU), a microprocessor, or any other device or combination of devices that is configured to respond to and execute instructions (e.g., code or coding) in a defined manner to achieve a desired result. In one example, a processor or computer includes, or is connected to, one or more memories storing the instructions or software that are executed by the processor or computer. Hardware components implemented by a processor or computer may execute the instructions or software, such as an operating system (OS) and one or more software applications that run on the OS, to perform the operations described in this application. The hardware components may also access, manipulate, process, create, and store data in response to execution of the instructions or software. For simplicity, the singular term "processor" or "computer" may be used in the description of the examples described in this application, but in other examples multiple processors or computers may be used, or a processor or computer may include multiple processing elements, or multiple types of processing elements, or both, and thus while some references may be made to a singular processor or computer, such references also are intended to refer to multiple processors or computers. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing. Thus, references to a processor herein mean processing circuitry (e.g., circuitry that includes one or more processing element(s) circuits). One or more processors comprising processing circuitry also refers to each processor comprising processing circuitry, as well as some or all of the one or more processors comprising the same processing circuitry. In addition, processors(s) and controller(s), as a non-limiting example, do not mean human processing or human control, but rather, refer to hardware components as described herein, as non-limiting examples.

The methods illustrated in, and discussed with respect to, FIGS. 1-7 that perform the operations described in this application are performed by computing hardware, for example, by one or more processors or computers, implemented as described above implementing the instructions (e.g., computer or processor/processing device readable instructions) or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations. References to a processor, or one or more processors, as a non-limiting example, configured to perform two or more operations refers to a processor or two or more processors being configured to collectively perform all of the two or more operations, as well as a configuration with the two or more processors respectively performing any corresponding one of the two or more operations (e.g., with a respective one or more processors being configured to perform each of the two or more operations, or any respective combination of one or more processors being configured to perform any respective combination of the two or more operations). Likewise, a reference to a processor-implemented method is a reference to a method that is performed by one or more processors or other processing or computing hardware of a device or system.

The instructions or software to control computing hardware, for example, one or more processors or computers, to implement the hardware components and perform the methods as described above may be written as computer programs, code segments, or other executable instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, and/or fixed in or on one or more non-transitory computer-readable storage media, and thus, not a signal per se. Thus, references herein to storage media mean storage media hardware, and does not mean transitory media, nor a signal per se. A non-transitory computer-readable storage medium may include a buffer in which data is temporarily stored. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD- Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as a multimedia card or a micro card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A quantum apparatus comprising:
a first electrode layer that extends in a first direction on a substrate;
a second electrode layer that extends in a second direction on the substrate;
a Josephson junction formed by an overlapping of the first electrode layer by the second electrode layer; and
capacitor pads that form a resonance circuit together with the Josephson junction,
wherein the Josephson junction has a first length that is defined as a length of a top edge, of the Josephson junction, along which the second electrode layer extends across the first electrode layer in the second direction, and has a second length that is defined as a length of a step edge of the Josephson junction where the second electrode layer extends upward to overlap or be above the first electrode layer, and
wherein a ratio of the first length to the second length corresponds to a resistance dispersion of the Josephson junction.

2. The quantum apparatus of claim 1, wherein the Josephson junction has a bonding area, defined by the first and second lengths, corresponding to a predetermined resistance of the Josephson junction.

3. The quantum apparatus of claim 1, wherein the Josephson junction has a bonding area, defined by the first and second lengths, corresponding to a predetermined resonant frequency of the resonant circuit.

4. The quantum apparatus of claim 1, wherein the resistance dispersion of the Josephson junction is a dispersion of respective normal resistances of Josephson junctions having a same configuration of the Josephson junction.

5. The quantum apparatus of claim 1, wherein the second length is greater than the first length.

6. The quantum apparatus of claim 1, wherein the first length is a length of the Josephson junction in the second direction, and the second length is a length of the Josephson junction in the first direction.

7. The quantum apparatus of claim 1,
wherein a first width of the first electrode layer at the Josephson junction defines the first length, and a second width of the second electrode layer at the Josephson junction defines the second length, and
wherein the resistance dispersion of the Josephson junction is defined by the first and second widths.

8. The quantum apparatus of claim 7, wherein the first width is different from the second width.

9. The quantum apparatus of claim 7, wherein the first width is less than the second width.

10. The quantum apparatus of claim 1, wherein the Josephson junction comprises a barrier layer arranged between the first electrode layer and the second electrode layer.

11. The quantum apparatus of claim 1, wherein the first and second directions are orthogonal or at a non-zero angle with respect each other.

12. The quantum apparatus of claim 1, wherein the first and second directions are in line and are opposing directions.

13. The quantum apparatus of claim 1, wherein the overlapping of the first electrode layer by the first electrode layer includes the second electrode layer extending upward from the substrate to be over the first electrode layer in the second direction and then descending downward from being over the first electrode layer to be on the substrate in the second direction.

14. The quantum apparatus of claim 1, wherein the resistance dispersion of the Josephson junction corresponds to a normal resistance of the Josephson junction that is within a first range of normal resistances along with other first Josephson junctions that also have the first and second lengths and a same first Josephson junction area as the Josephson junction, with the first range being smaller than another range of normal resistances of other second Josephson junctions that have the same first Josephson junction area but a greater ratio of a corresponding first length to a corresponding second length of each of the second Josephson junctions.

15. The quantum apparatus of claim 14, further comprising:
a quantum integrated circuit that includes the Josephson junction and the other first Josephson junctions, all of which have corresponding normal resistances within the first range; and
a control circuit configured to control the quantum integrated circuit.

16. A quantum apparatus comprising:
a substrate; and
plural quantum devices arranged on the substrate,
wherein each of the quantum devices comprises:
a first electrode layer that extends in a first direction on the substrate;
a second electrode layer that extends in a second direction on the substrate;
a Josephson junction formed by an overlapping of the first electrode layer by the second electrode layer; and
capacitor pads that form a resonance circuit together with the Josephson junction,
wherein each of the Josephson junctions has a first length that is defined as a length of a top edge, of a corresponding Josephson junction, along which the second electrode layer extends across the first electrode layer in the second direction, and has a second length that is defined as a length of a step edge of the corresponding Josephson junction where the second electrode layer extends upward to overlap or be above the first electrode layer,
wherein all of the Josephson junctions have a same ratio of the first length to the second length, the ratio corresponding to a resistance dispersion that each of the Josephson junctions satisfy, and
wherein the substrate and the plural quantum devices are arranged as a quantum integrated circuit.

17. The quantum apparatus of claim 16, wherein
each of the Josephson junctions has a bonding area, defined by the first and second lengths, corresponding to a predetermined resistance of the Josephson junctions.

18. The quantum apparatus of claim 16, wherein each of the Josephson junctions has a bonding area, defined by the first and second lengths, corresponding to a predetermined resonant frequency of the resonant circuit.

19. A quantum apparatus comprising:
a quantum integrated circuit including a substrate and plural quantum devices arranged on the substrate; and
a control circuit configured to control the quantum integrated circuit,
wherein each of the plural quantum devices comprises:
a first electrode layer that extends in a first direction on the substrate;
a second electrode layer that extends in a second direction on the substrate;
a Josephson junction formed by an overlapping of the first electrode layer by the second electrode layer; and
capacitor pads that form a resonance circuit together with the Josephson junction,
wherein each of the Josephson junctions has a first length that is defined as a length of a top edge, of a corresponding Josephson junction, along which the second electrode layer extends across the first electrode layer in the second direction, and has a second length that is defined as a length of a step edge of the corresponding Josephson junction where the second electrode layer extends upward to overlap or be above the first electrode layer, and
wherein all of the Josephson junctions have a same ratio of the first length to the second length, the ratio corresponding to a resistance dispersion that each of the Josephson junctions satisfy.

20. The quantum apparatus of claim 18, wherein each of the Josephson junctions has a bonding area, defined by the first and second lengths, corresponding to a predetermined resistance of the Josephson junctions.
